(19) United States
(12) Patent Application Publication
(10) Pub. No.: US 2026/0282818 A1
(43) Pub. Date: Sep. 17, 2026

(54) SUBSTRATE STORAGE CONTAINER AND METHOD FOR MANUFACTURING SUBSTRATE STORAGE CONTAINER

(71) Applicant: Shin-Etsu Polymer Co., Ltd., Chiyoda-ku, Tokyo (JP)

(72) Inventors: Hiroshi MIMURA, Saitama (JP); Akihiro HASEGAWA, Niigata (JP)

(21) Appl. No.: 19/471,373

(22) PCT Filed: Dec. 25, 2023
(86) PCT No.: PCT/JP2023/046476

§ 371 Date: Oct. 1, 2025

(30) Foreign Application Priority Data
Apr. 12, 2023 (JP) 2023-065174

(51) Int. Cl. H10P 72/10; B29C 45/00; B29L 31/00

(52) U.S. Cl. CPC H10P 72/1922; B29C 45/0025; B29C 45/0046; B29L 2031/712

(57) ABSTRACT

A substrate storage container includes a container body capable of storing a substrate. The container body includes: a wall portion defining a storage space for storing the substrate; a thin portion integrally formed with the wall portion and being thinner than the wall portion; and one or more parting lines provided on an outer surface of the wall portion and formed along a boundary between a mold body and a mold insert used for injection molding of the container body. The one or more parting lines include a first parting line passing through the thin portion.

### TECHNICAL FIELD

The present disclosure relates to a substrate storage container and a method for manufacturing a substrate storage container.

### BACKGROUND ART

A substrate storage container for storing a substrate such as a semiconductor wafer is known. For example, Patent Literature 1 describes a substrate storage container including a container body capable of storing a substrate, and a lid capable of closing an opening of the container body.

### CITATION LIST

### Patent Literature

Patent Literature 1: International Publication No. 2020/122261

### SUMMARY OF INVENTION

### Technical Problem

In the substrate storage container described in Patent Literature 1, the container body is formed by injecting molten resin into a mold for injection molding. Since gas is generated from the molten resin, there is a risk that the molten resin cannot completely fill a cavity in the mold if gas accumulates in the cavity. In such a case, molding defects such as deformation and burning may occur in the molded product.

The present disclosure describes a substrate storage container and a method for manufacturing a substrate storage container that can improve the quality of the substrate storage container.

### Solution to Problem

A substrate storage container according to one aspect of the present disclosure includes a container body capable of storing a substrate. The container body includes: a wall portion defining a storage space for storing the substrate; a thin portion integrally formed with the wall portion and being thinner than the wall portion; and one or more parting lines provided on an outer surface of the wall portion and formed along a boundary between a mold body and a mold insert used for injection molding of the container body. The one or more parting lines include a first parting line passing through the thin portion.

In the injection molding of the container body, the container body is formed by injecting molten resin from the gate provided in the mold into the cavity within the mold. When the flow rate of the molten resin increases in the cavity within the mold, shear heat increases, and more gas may be generated from the molten resin. In the substrate storage container, since the thin portion, which is thinner than the wall portion, is integrally formed with the wall portion, the flow rate of the molten resin is higher in a region for forming the thin portion than in a region for forming the wall portion in the cavity within the mold. For this reason, gas is likely to accumulate in the region for forming the thin portion in the cavity within the mold. According to the above configuration, since the first parting line passes through the thin portion, it can be said that the boundary between the mold body and the mold insert was located in a portion of the mold that defines the region for forming the thin portion. Therefore, the gas accumulated in the region can be released to the outside of the mold through the boundary between the mold body and the mold insert. Accordingly, since the likelihood of gas accumulating in the above-described region is reduced, that region can be filled with the molten resin. As a result, it is possible to improve the quality of the substrate storage container.

In some embodiments, the container body may further include a gate mark provided on the wall portion, the gate mark being a mark of a gate into which molten resin flows during the injection molding. The one or more parting lines may include a second parting line provided at a position spaced from the gate mark by a predetermined distance or more. In injection molding, the molten resin injected from the gate flows through the cavity in the mold while generating gas. For this reason, gas tends to accumulate more readily as the distance from the gate increases. According to the above configuration, since the second parting line is provided at a position spaced from the gate mark by the predetermined distance or more, it can be said that the boundary between the mold body and the mold insert was located at that position. Therefore, the gas accumulated in the cavity within the mold can be released from the boundary between the mold body and the mold insert. As a result, it is possible to further improve the quality of the substrate storage container.

In some embodiments, the above-described substrate storage container may further include a label attached to the outer surface of the wall portion along any of the one or more parting lines. In this case, it is possible to suppress variations in the attachment position of the label for each substrate storage container without providing a dedicated line or the like for attaching the label.

In some embodiments, the label may include a base material and an adhesive material provided on one surface of the base material. A groove may be provided in the adhesive material. In this case, gas generated from the wall portion is released to the outside through the groove provided in the adhesive material. Accordingly, lifting or blistering of the label due to gas can be suppressed, and the likelihood of the label peeling off can be reduced.

A method for manufacturing a substrate storage container according to another aspect of the present disclosure includes: preparing a mold for injection molding of a container body including a wall portion that defines a storage space for storing a substrate, the mold including a first mold body, a second mold body, and a first mold insert fitted into the first mold body; and forming the container body by injecting molten resin into a cavity within the mold from a gate provided in the mold. A boundary between the first mold insert and the first mold body is located in a portion of the mold that, in the cavity within the mold, defines a region where a flow rate of the molten resin is higher than in a region for forming the wall portion.

In the method for manufacturing a substrate storage container, the container body is formed by injecting molten resin from the gate provided in the mold into the cavity within the mold. When the flow rate of the molten resin increases in the cavity within the mold, shear heat increases, and more gas may be generated from the molten resin. For this reason, gas is likely to accumulate in a region where the flow rate of the molten resin increases in the cavity within the mold. According to the above configuration, since the boundary between the first mold insert and the first mold body is located in a portion of the mold that defines the region, the gas accumulated in the region can be released to the outside of the mold through the boundary between the first mold insert and the first mold body. Accordingly, since the likelihood of gas accumulating in the above-described region is reduced, the region can be filled with the molten resin. As a result, it is possible to improve the quality of the substrate storage container.

In some embodiments, the mold may further include a second mold insert fitted into the first mold body or the second mold body. A boundary between the second mold insert and the first mold body or a boundary between the second mold insert and the second mold body may be located in a portion of the mold that defines a region of the cavity within the mold that is last filled with the molten resin injected from the gate. The molten resin injected from the gate flows through the cavity in the mold while generating gas. For this reason, gas is likely to accumulate in the region of the cavity within the mold that is last filled with the molten resin. According to the above configuration, since the boundary between the second mold insert and the first mold body or the second mold body is located in a portion of the mold that defines the region, the gas accumulated in the region can be released. As a result, it is possible to further improve the quality of the substrate storage container.

### Advantageous Effects of Invention

According to the present disclosure, it is possible to improve the quality of a substrate storage container.

### BRIEF DESCRIPTION OF DRAWINGS

FIG. 1 is an exploded perspective view of a substrate storage container according to an embodiment.

FIG. 2 is a top view of the substrate storage container shown in FIG. 1.

FIG. 3 is a right side view of the substrate storage container shown in FIG. 1.

FIG. 4 is an enlarged perspective view showing a part of the substrate storage container shown in FIG. 1.

FIG. 5 is a rear view of the substrate storage container shown in FIG. 1.

FIG. 6 is a bottom view of the substrate storage container shown in FIG. 1.

FIG. 7 is a schematic diagram for explaining a mold used for injection-molding the container body shown in FIG. 1.

FIG. 8 is a diagram showing an example of an attachment position of a label.

FIG. 9 is a cross-sectional view taken along line IX-IX in FIG. 8.

### DESCRIPTION OF EMBODIMENTS

Hereinafter, embodiments of the present disclosure will be described in detail with reference to the drawings. In the description of the drawings, the same elements are denoted by the same reference numerals, and redundant descriptions will be omitted. In each figure, an XYZ coordinate system is shown. The Y-axis direction is a direction that intersects (here, is orthogonal to) the X-axis direction and the Z-axis direction. The Z-axis direction is a direction that intersects (here, is orthogonal to) the X-axis direction and the Y-axis direction. For example, the X-axis direction is a left-right direction (width direction), the Y-axis direction is a front-rear direction (depth direction), and the Z-axis direction is an up-down direction (height direction). For convenience of description, the terms “front,” “rear,” “up,” “down,” “left,” and “right” are used, however, these directional terms are not intended to be limiting.

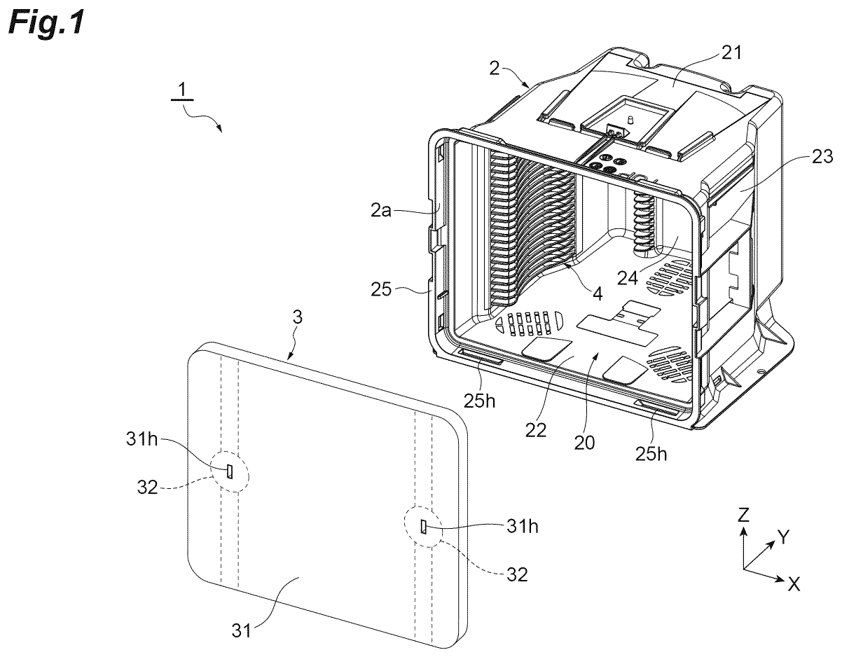

A substrate storage container according to an embodiment will be described with reference to FIG. 1. FIG. 1 is an exploded perspective view of a substrate storage container according to an embodiment. The substrate storage container 1 shown in FIG. 1 is a container for storing a plurality of substrates. The substrate storage container 1 is referred to as, for example, a Front Opening Shipping Box (FOSB) and is used for transporting substrates between factories. The substrate storage container 1 conforms to, for example, Semiconductor Equipment and Materials International (SEMI) standards. An example of the substrate is a semiconductor wafer. The substrate has, for example, a disk shape with a diameter of 300 mm and a thickness of 775 μm. The number of substrates that can be stored in the substrate storage container 1 is arbitrarily determined, and is, for example, 25.

The substrate storage container 1 includes a container body 2, a lid 3, and a pair of supports 4.

The container body 2 is a front-open type container with an opening 2a provided on the front (front surface). The container body 2 is capable of storing a plurality of substrates. Specifically, the container body 2 stores a plurality of substrates in a state of being stacked with intervals therebetween in the up-down direction. Substrates are loaded into and unloaded from the container body 2 through the opening 2a.

The container body 2 includes a top plate 21 (wall portion), a bottom plate 22 (wall portion), a pair of side walls 23 (wall portions), a rear wall 24 (wall portion), and a frame body 25. The top plate 21, the bottom plate 22, the pair of side walls 23, and the rear wall 24 define a storage space 20 for storing a plurality of substrates. The frame body 25 is a rectangular frame and is provided so as to extend across the front end of the top plate 21, the front end of the bottom plate 22, and the front ends of the pair of side walls 23. The frame body 25 defines the opening 2a. The frame body 25 is bent to form an outwardly flaring step, and the surface of the step portion functions as a seal surface with which a sealing member such as a gasket comes into contact. Details of the container body 2 will be described later.

The lid 3 is a member for closing the opening 2a of the container body 2. The lid 3 is detachably attached to the frame body 25. The lid 3 hermetically closes the opening 2a of the container body 2 via a sealing member such as a gasket. The lid 3 includes a lid body 31 and a locking mechanism 32.

The lid body 31 is a main body portion of the lid 3. The lid body 31 is a rectangular plate member. A keyhole 31h is provided on the front surface of the lid body 31. A key (not shown) is inserted into the keyhole 31h. The locking mechanism 32 locks or unlocks the lid 3 upon operation of the key inserted into the keyhole 31h. The locking mechanism 32 includes a latch (not shown). With the lid 3 closing the opening 2a of the container body 2, the lid 3 is locked by operating the key to cause the latch to fit into a locking hole 25h provided in the frame body 25. With the lid 3 locked, the lid 3 is unlocked by operating the key to pull the latch out of the locking hole 25h.

Examples of the material for the container body 2 and the lid 3 include thermoplastic resins such as polycarbonate, cycloolefin polymer, and liquid crystal polymer. A conductive agent, various antistatic agents, an ultraviolet absorber, and the like may be appropriately added to this thermoplastic resin. Examples of the conductive agent include conductive carbon, conductive fiber, metal fiber, and conductive polymer.

The pair of supports 4 are members for supporting the substrates. Each support 4 is provided on an inner surface of the side wall 23 and protrudes from the inner surface of the side wall 23 into the storage space 20. A plurality of grooves extending in the front-rear direction is provided in each support 4. The plurality of grooves may have a shape that is recessed toward the side wall 23. The plurality of grooves is arranged in parallel in the up-down direction. A substrate is supported by inserting both left and right end portions of the substrate into grooves located at the same height provided in the pair of supports 4. Each support 4 may be integrally formed with the container body 2 by insert molding, or may be assembled to the container body 2 in an assembly-type manner. Examples of the constituent material of each support 4 include thermoplastic resins such as polycarbonate, cycloolefin polymer, liquid crystal polymer, polybutylene terephthalate, and polyether ether ketone.

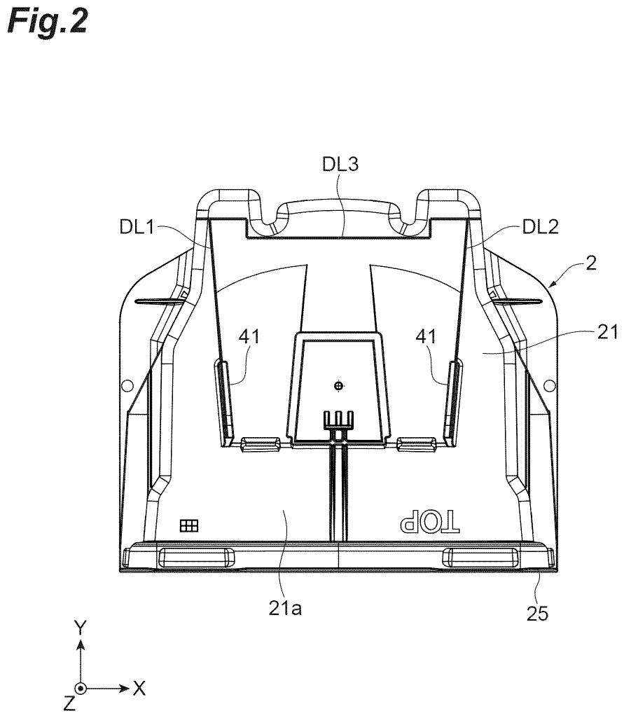

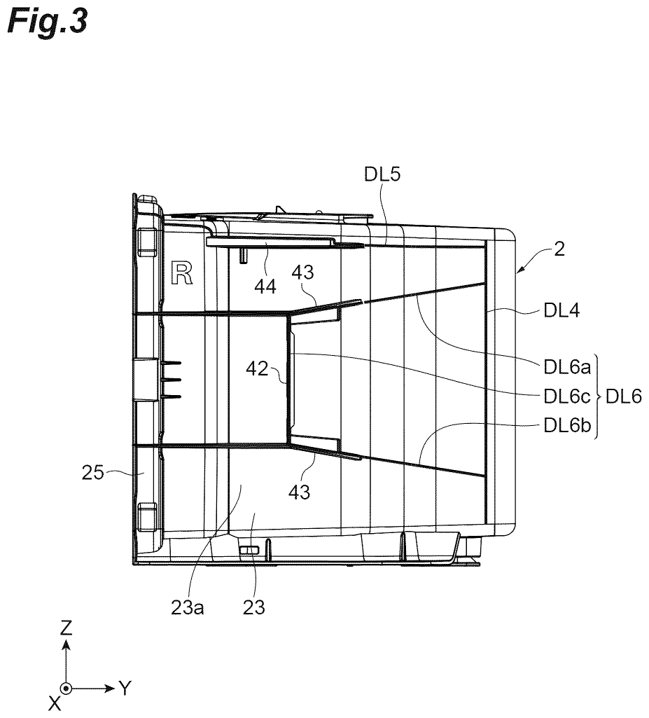

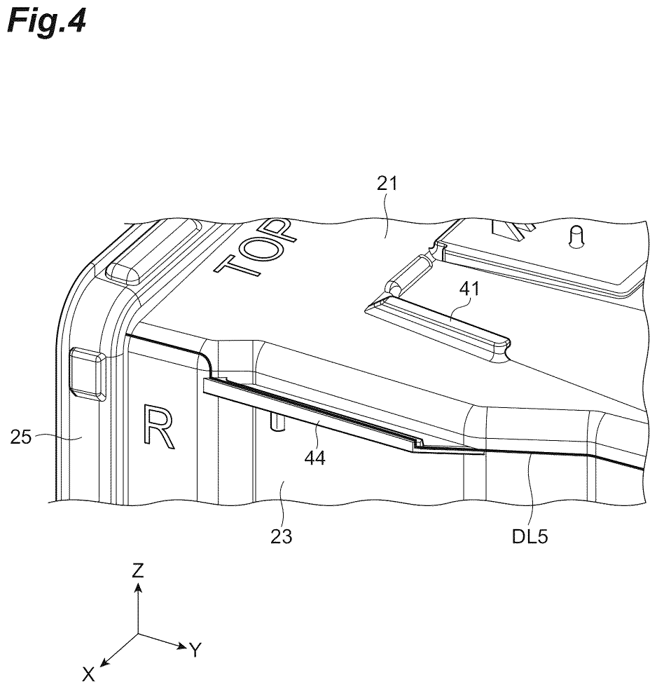

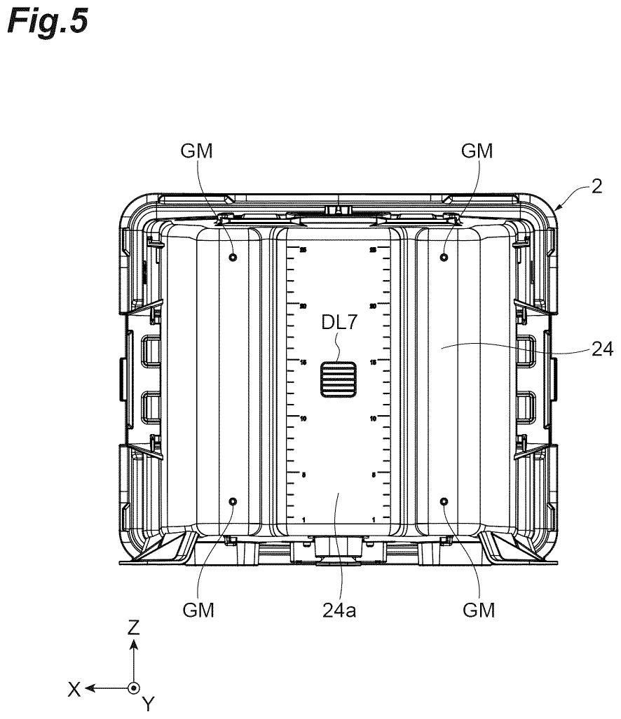

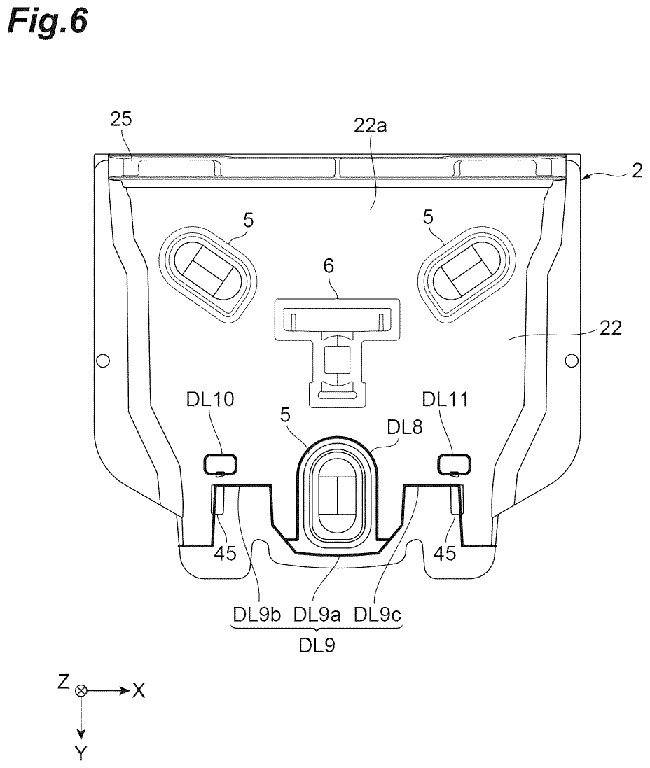

Next, the container body 2 will be described in detail with reference to FIGS. 2 to 6. FIG. 2 is a top view of the substrate storage container shown in FIG. 1. FIG. 3 is a right side view of the substrate storage container shown in FIG. 1. FIG. 4 is an enlarged perspective view showing a part of the substrate storage container shown in FIG. 1. FIG. 5 is a rear view of the substrate storage container shown in FIG. 1. FIG. 6 is a bottom view of the substrate storage container shown in FIG. 1.

As shown in FIG. 2, the container body 2 further includes a pair of ribs 41 (thin portions) and parting lines DL1 to DL3. The pair of ribs 41 are portions for attaching a robotic handling flange. The robotic handling flange is a component gripped by a transfer robot that transports the substrate storage container 1. Each rib 41 is integrally formed with the top plate 21 and is provided on an upper surface 21a (outer surface) of the top plate 21. The pair of ribs 41 are arranged symmetrically with respect to a center line in the left-right direction of the upper surface 21a, and extend in the front-rear direction so as to separate from each other toward the rear. The thickness (width) of each rib 41 is thinner than the thickness of the top plate 21.

Each of the parting lines DL1 to DL3 is integrally formed with the top plate 21 and is provided on the upper surface 21a of the top plate 21. Each of the parting lines DL1 to DL3 is a fine linear protrusion formed along a boundary between a mold body (described later) and a mold insert (described later) used for injection molding. The parting line DL1 (first parting line) extends in a straight line on the upper surface of one of the ribs 41 from the front end of the rib 41 to the rear end thereof, and further extends in a straight line on the upper surface 21a from the rear end of the rib 41 to the peripheral edge of the upper surface 21a. The parting line DL1 is connected to the parting line DL3. The parting line DL2 (first parting line) extends in a straight line on the upper surface of the other rib 41 from the front end of the rib 41 to the rear end thereof, and further extends in a straight line on the upper surface 21a from the rear end of the rib 41 to the peripheral edge of the upper surface 21a. The parting line DL2 is connected to the parting line DL3. The parting line DL3 extends on the upper surface 21a from the left edge to the right edge along the rear edge of the upper surface 21a.

As shown in FIGS. 3 and 4, the container body 2 further includes a flange 42 (thin portion), a pair of ribs 43 (thin portions), a rib 44 (thin portion), and parting lines DL4 to DL6. The flange 42 is a portion used as a handhold by an operator when carrying the substrate storage container 1. The flange 42 is integrally formed with the side wall 23 and is provided on an outer surface 23a of the side wall 23. The flange 42 extends in the up-down direction in the vicinity of the center of the outer surface 23a and interconnects the pair of ribs 43. The flange 42 has a plate-like shape that is thinner than the side wall 23.

The pair of ribs 43 are portions that reinforce the strength of the flange 42. Each rib 43 is integrally formed with the side wall 23 and is provided on the outer surface 23a of the side wall 23. The pair of ribs 43 are arranged symmetrically with respect to a center line in the up-down direction of the outer surface 23a. Each rib 43 includes a front portion and a rear portion. The front portions of the pair of ribs 43 extend substantially parallel in the front-rear direction. The rear portions of the pair of ribs 43 are inclined so as to separate from each other toward the rear. Each rib 43 has a plate-like shape that is thinner than the side wall 23.

The rib 44 is a portion for attaching a manual handle. The manual handle is a component gripped by an operator when carrying the substrate storage container 1. The rib 44 is integrally formed with the side wall 23 and is provided on the outer surface 23a of the side wall 23. The rib 44 is provided in the vicinity of the upper edge of the outer surface 23a on the front side of the outer surface 23a and extends in the front-rear direction. The rib 44 has a plate-like shape that is thinner than the side wall 23.

Each of the parting lines DL4 to DL6 is integrally formed with the side wall 23 and is provided on the outer surface 23a of the side wall 23. Each of the parting lines DL4 to DL6 is a fine linear protrusion formed along a boundary between a mold body (described later) and a mold insert (described later) used for injection molding. The parting line DL4 extends in a straight line, in the vicinity of the rear edge of the outer surface 23a, from the upper edge to the lower edge of the outer surface 23a. The parting line DL5 (first parting line) extends on the outer surface 23a in a straight line from the parting line DL4 to the rear end of the rib 44, extends along the outer edge of the rib 44 from the rear end to the front end of the rib 44, and further extends from the front end of the rib 44, passes through a boundary portion between the side wall 23 and the top plate 21, and reaches the front end of the frame body 25.

The parting line DL6 (first parting line) includes a portion DL6a, a portion DL6b, and a portion DL6c. The portion DL6a extends in a straight line on a tip surface of one of the ribs 43 from the front end of the rib 43 to the rear end thereof, and further extends in a straight line on the outer surface 23a from the rear end of the rib 43 to the parting line DL4. The portion DL6b extends in a straight line on a tip surface of the other rib 43 from the front end of the rib 43 to the rear end thereof, and further extends in a straight line on the outer surface 23a from the rear end of the rib 43 to the parting line DL4. The portion DL6c is a portion that connects the front end of the portion DL6a and the front end of the portion DL6b, and extends on a tip surface of the flange 42 from the upper end to the lower end of the flange 42.

As shown in FIG. 5, the container body 2 further includes a plurality of gate marks GM and a parting line DL7 (second parting line). The gate mark GM is a mark of a gate (described later) into which molten resin flows during injection molding. In the example shown in FIG. 5, the container body 2 includes four gate marks GM. Each gate mark GM is integrally formed with the rear wall 24 and is provided on a rear surface 24a of the rear wall 24. Each gate mark GM is a fine annular protrusion. Two gate marks GM are provided near the upper edge of the rear surface 24a, and two gate marks GM are provided near the lower edge of the rear surface 24a. The two gate marks GM provided near the upper edge are spaced apart from each other in the left-right direction. The two gate marks GM provided near the lower edge are spaced apart from each other in the left-right direction.

The parting line DL7 is integrally formed with the rear wall 24 and is provided on the rear surface 24a of the rear wall 24. The parting line DL7 is a fine linear protrusion formed along a boundary between a mold body (described later) and a mold insert (described later) used for injection molding. The parting line DL7 is provided near the center of the rear surface 24a and is substantially equidistant from the four gate marks GM. The parting line DL7 includes a rectangular frame portion and a plurality of linear portions. The plurality of linear portions is arranged in the up-down direction, and each extends from the right side edge of the frame portion to the left side edge thereof.

As shown in FIG. 6, the substrate storage container 1 further includes a positioning member 5 and a holding member 6. The positioning member 5 is a member used by an external device such as a load port to position the substrate storage container 1 (container body 2). The positioning member 5 is provided on the bottom plate 22 so as to protrude downward from a bottom surface 22a of the bottom plate 22. The positioning member 5 has a V-shaped surface that is recessed in a V-shape toward the bottom plate 22 (i.e., upward). The V-shaped surface may be subjected to a surface treatment to improve wear resistance and slidability, as necessary. In the present embodiment, the substrate storage container 1 includes three positioning members 5. Each positioning member 5 may be integrally formed with the container body 2 by insert molding, or may be assembled to the container body 2 in an assembly-type manner. Examples of the constituent material of each positioning member include thermoplastic resins such as polycarbonate, cycloolefin polymer, liquid crystal polymer, polybutylene terephthalate, and polyether ether ketone.

The holding member 6 is a member configured to detachably hold, on the container body 2, a fixing member (not shown) used by an external device such as a load port to secure the substrate storage container 1 (container body 2). The holding member 6 is joined to the bottom plate 22. The holding member 6 may be integrally formed with the container body 2 by insert molding, or may be assembled to the container body 2 in an assembly-type manner. Examples of the constituent material of the holding member 6 include thermoplastic resins such as polycarbonate, cycloolefin polymer, liquid crystal polymer, polybutylene terephthalate, and polyether ether ketone.

As shown in FIG. 6, the container body 2 further includes a pair of claw portions 45 and parting lines DL8 to DL11. The pair of claw portions 45 are portions for fitting an info pad plate used to identify the substrates stored in the substrate storage container 1. A barcode label may be attached to the info pad plate, or a radio frequency identification (RFID) tag may be held therein. Each claw portion 45 is integrally formed with the bottom plate 22 and is provided on the bottom surface 22a of the bottom plate 22. The pair of claw portions 45 are arranged symmetrically with respect to a center line in the left-right direction of the bottom surface 22a. Each claw portion 45 has a plate-like shape that is thicker than the bottom plate 22.

Each of the parting lines DL8 to DL11 is integrally formed with the bottom plate 22 and is provided on the bottom surface 22a of the bottom plate 22. Each of the parting lines DL8 to DL11 is a fine linear protrusion formed along a boundary between a mold body (described later) and a mold insert (described later) used for injection molding. The parting line DL8 has a U-shape that opens toward the rear. The parting line DL8 is provided so as to surround the positioning member 5 located at the rear, and both ends of the parting line DL8 are connected to the parting line DL9.

The parting line DL9 has a shape that is symmetrical with respect to a center line in the left-right direction of the bottom surface 22a. The parting line DL9 includes a portion DL9a, a portion DL9b, and a portion DL9c. The portion DL9a is a portion provided between the positioning member 5 located at the rear and the rear edge of the bottom surface 22a, and has a U-shape that opens toward the front. The portion DL9a extends along the rear edge of the bottom surface 22a and sandwiches the parting line DL8 in the left-right direction. The portion DL9b and the portion DL9c are symmetrical with respect to the center line in the left-right direction of the bottom surface 22a. The portion DL9b is connected to the left end of the portion DL9a, passes through a tip surface (lower end surface) of the left claw portion 45 in the front-rear direction, and extends to the left end of the bottom surface 22a. The portion DL9c is connected to the right end of the portion DL9a, passes through a tip surface (lower end surface) of the right claw portion 45 in the front-rear direction, and extends to the right end of the bottom surface 22a.

The parting line DL10 and the parting line DL11 are arranged symmetrically with respect to the center line in the left-right direction of the bottom surface 22a. The parting line DL10 has a rectangular annular shape and is provided in front of the left claw portion 45. The parting line DL 11 has a rectangular annular shape and is provided in front of the right claw portion 45.

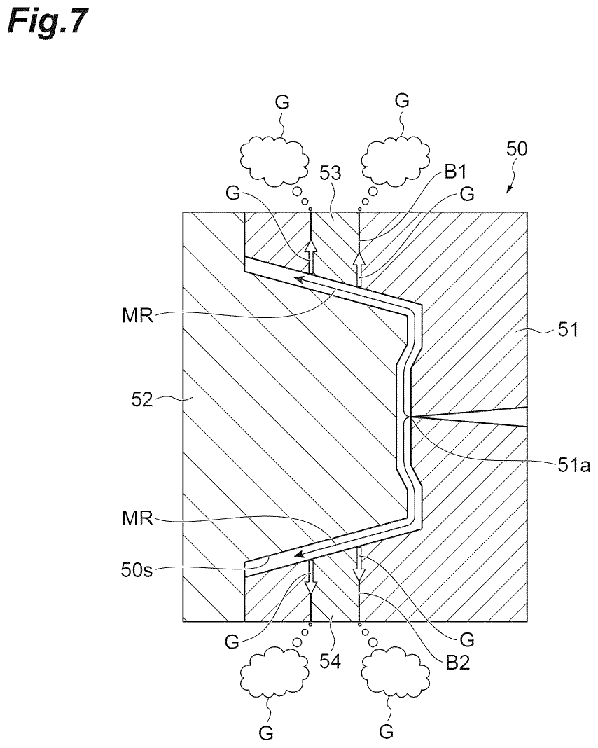

Next, a method for manufacturing the substrate storage container 1 will be described with reference to FIG. 7. FIG. 7 is a schematic diagram for explaining a mold used for injection-molding the container body shown in FIG. 1.

As shown in FIG. 7, first, a step of preparing a mold 50 for injection-molding the container body 2 is performed. The mold 50 is, for example, a metal mold. The mold 50 includes a mold body 51 (first mold body), a mold body 52 (second mold body), and a plurality of mold inserts. A mold insert is a mold component that is fitted into a mold body. In the example shown in FIG. 7, a mold insert 53 (first mold insert) and a mold insert 54 (second mold insert) are illustrated as mold inserts. In FIG. 7, the mold insert 53 and the mold insert 54 are schematically drawn for ease of later description and are not shown at their exact positions. The mold inserts 53 and 54 are fitted into the mold body 51, and when the mold body 51 and the mold body 52 are assembled together, a cavity 50s is formed within the mold 50.

The mold body 51 includes a gate 51a. The gate 51a is an injection port for injecting molten resin MR (resin in a molten state) into the cavity 50s in the mold 50. Each mold insert is provided in a region of the cavity 50s in the mold 50 where gas G generated from the molten resin MR is likely to accumulate. Specifically, the position of the mold insert is determined such that a boundary between the mold insert and the mold body (the mold body 51 or the mold body 52) is located in a portion of the mold 50 that defines a region where the gas G is likely to accumulate in the cavity 50s.

For example, a boundary B1 between the mold insert 53 and the mold body 51 is located in a portion of the mold 50 that, in the cavity 50s, defines a region where a flow rate of the molten resin MR is higher than in a region for forming the wall portions (that is, the top plate 21, the bottom plate 22, the side walls 23, and the rear wall 24) that define the storage space 20. Specifically, the boundary B1 is located in a portion of the mold 50 that defines a region for forming the thin portions (for example, the rib 41, the rib 43, and the flange 42) that are thinner than the wall portions.

A boundary B2 between the mold insert 54 and the mold body 51 is located in a portion of the mold 50 that defines a last-to-fill region of the cavity 50s. The last-to-fill region is a region that is last filled with the molten resin MR injected from the gate 51a. For example, within the cavity 50s, the last-to-fill region is a region at which the flow length of the molten resin MR is greatest. The flow length is a distance along the melt flow path of the molten resin MR from the gate 51a. Where the molten resin MR is injected from a plurality of gates 51a, the shortest of the distances along the melt flow paths of the molten resin MR from all the gates 51a is used as the flow length. For example, as shown in FIG. 5, when the molten resin MR is injected into the cavity 50s from four gates 51a, a region located at substantially equal distances from the four gates 51a constitutes the last-to-fill region. Note that, since the last-to-fill region is an area of a certain size within the cavity 50s, the expression “last filled with the molten resin MR” does not strictly mean that it is the very last to be filled with the molten resin MR.

Subsequently, a step of forming the container body 2 by injecting the molten resin MR from the gate 51a into the cavity 50s is performed. The molten resin MR is injected into the cavity 50s at a predetermined pressure. At this time, the gas G generated from the molten resin MR is released to the outside of the mold 50 from the boundary between the mold body and the mold insert, and the molten resin MR slightly enters the boundary between the mold body and the mold insert. Then, after the cavity 50s has been filled with the molten resin MR, the molten resin MR is cooled to solidify, thereby forming the container body 2. Parting lines (for example, parting lines DL1 to DL11) are formed on the outer surface of the container body 2 along the boundary between the mold body and the mold insert. For example, the boundary B1 forms parting lines (for example, parting lines DL1, DL2, DL5, and DL6) that pass through the thin portions. The boundary B2 forms a parting line (for example, parting line DL7) located in the last-to-fill region. Then, the mold 50 is demolded from the container body 2.

Through the foregoing steps, the substrate storage container 1 is manufactured.

In the method for manufacturing the substrate storage container 1 described above, the container body 2 is formed by injecting the molten resin MR from the gate 51a provided in the mold 50 into the cavity 50s in the mold 50. When the flow rate of the molten resin MR increases in the cavity 50s, shear heat increases, and more gas G may be generated from the molten resin MR. For this reason, gas G is likely to accumulate in a region where the flow rate of the molten resin MR increases in the cavity 50s. For example, in the substrate storage container 1, since the thin portions (for example, the rib 41, the flange 42, the rib 43, and the rib 44), which are thinner than the wall portions (the top plate 21, the bottom plate 22, the side walls 23, and the rear wall 24) defining the storage space 20, are integrally formed with the wall portions, the flow rate of the molten resin MR is higher in a region for forming the thin portions than in a region for forming the wall portions in the cavity 50s. For this reason, gas G is likely to accumulate in the region for forming the thin portions in the cavity 50s. In contrast, in the mold 50, since the boundary between the mold insert and the mold body is located in a portion of the mold 50 that defines the region where the flow rate of the molten resin MR increases, the gas G accumulated in the region can be released to the outside of the mold 50 through the boundary between the mold insert and the mold body. Therefore, since the likelihood of gas G accumulating in the above-described region is reduced, that region can be filled with the molten resin MR. As a result, it is possible to improve the quality of the substrate storage container 1.

The molten resin MR injected from the gate 51a flows through the cavity 50s while generating gas G. For this reason, in the cavity 50s, gas G tends to accumulate more readily as the distance from the gate 51a increases; in particular, gas G is likely to accumulate in the last-to-fill region that is last filled with the molten resin MR. In contrast, in the mold 50, since the boundary between the mold insert and the mold body is located in a portion of the mold 50 that defines the last-to-fill region, the gas G accumulated in the last-to-fill region can be released. As a result, it is possible to improve the quality of the substrate storage container 1.

The substrate storage container and the method for manufacturing a substrate storage container according to the present disclosure are not limited to the above-described embodiments.

It is sufficient that the parting line be provided on at least one of the top plate 21, the bottom plate 22, the pair of side walls 23, and the rear wall 24.

The container body 2 is not limited to including the parting line provided at a position corresponding to the last-to-fill region, and may include a parting line (second parting line) provided at a position spaced from the gate mark GM by a predetermined distance or more. In other words, the boundary between the mold body and the mold insert need not be located in the last-to-fill region, and may be located at a position spaced from the gate 51a by a predetermined distance or more. As described above, in the cavity 50s, gas G tends to accumulate more readily as the distance from the gate 51a increases. Therefore, the gas G accumulated in the cavity 50s can be released from the boundary between the mold body and the mold insert. As a result, it is possible to further improve the quality of the substrate storage container 1.

In the above embodiments, the mold insert 53 and the mold insert 54 are fitted into the mold body 51, but at least one of the mold insert 53 and the mold insert 54 may be fitted into the mold body 52. Each mold insert is fitted into either the mold body 51 or the mold body 52.

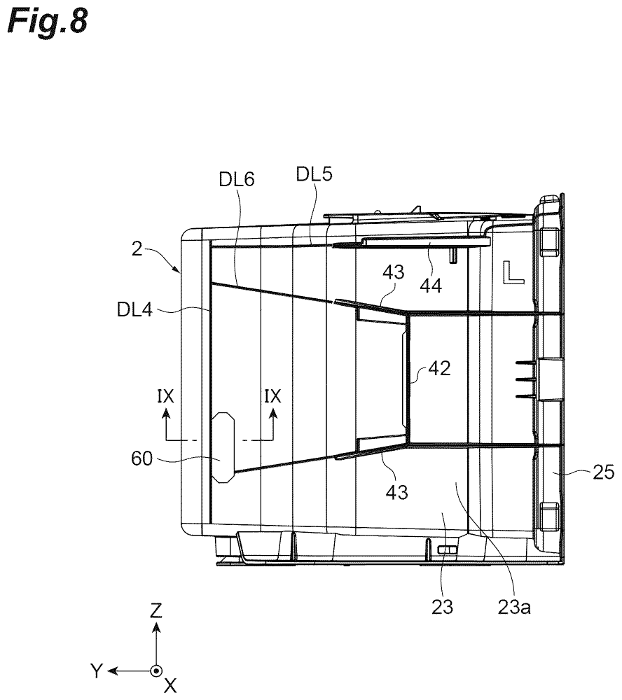

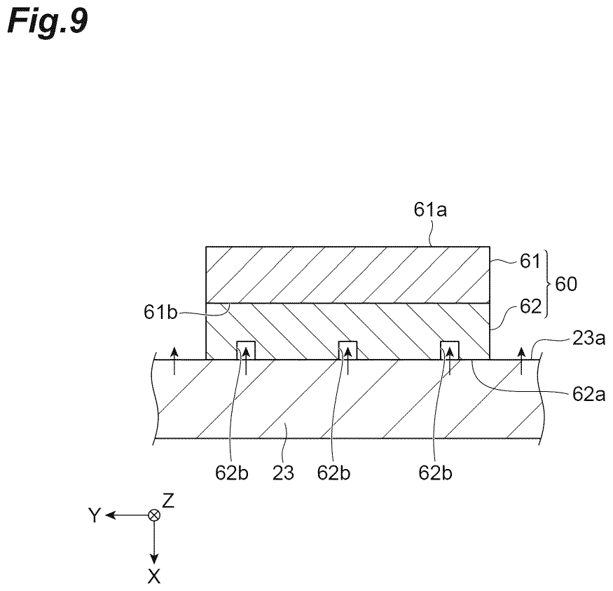

As shown in FIG. 8, the substrate storage container 1 may further include a label 60. The label 60 is attached to the outer surface of the wall portion along any of the parting lines. As shown in FIG. 9, the label 60 includes a base material 61 and an adhesive material 62. Information indicating the type of substrate stored in the substrate storage container 1 or the like is printed on a front surface 61a of the base material 61. The adhesive material 62 is provided on a back surface 61b (one surface) of the base material 61. The adhesive material 62 is provided over the entire back surface 61b of the base material 61. A plurality of grooves 62b is provided on a surface 62a of the adhesive material 62 opposite to the base material 61 (a surface that comes into contact with the container body 2). Each groove 62b is a fine groove. Each groove 62b is provided in the adhesive material 62 such that at least one of both ends of the groove 62b communicates with an external space of the substrate storage container 1 in a state where the label 60 is attached to the container body 2.

When the substrate storage container 1 includes the label 60, a step of attaching the label 60 to the container body 2 is performed after the container body 2 is formed. In this step, the label 60 is attached to the outer surface of the wall portion with reference to any of the parting lines. In the example shown in FIG. 8, the label 60 is attached along the parting line DL4. Specifically, the label 60 is attached to the outer surface 23a of the side wall 23 such that one side of the label 60 is located on the parting line DL4.

In this case, it is possible to suppress variations in the attachment position of the label 60 for each substrate storage container 1 without providing a dedicated line or the like for attaching the label 60.

After the substrate storage container 1 is washed, the substrate storage container 1 may be dried by applying heat to the substrate storage container 1. In this way, when the container body 2 is heated, gas may be generated from the container body 2. For example, if gas is generated from the wall portion to which the label 60 is attached, the label 60 may lift or blister due to the gas, creating a risk that the label 60 will peel off. In contrast, since the grooves 62b are provided in the adhesive material 62 of the label 60, the gas generated from the wall portion is released to the outside through the grooves 62b provided in the adhesive material 62. Accordingly, lifting or blistering of the label 60 due to gas can be suppressed, and the likelihood of the label 60 peeling off can be reduced.

### Reference Signs List

1 . . . substrate storage container, 2 . . . container body, 20 . . . storage space, 21 . . . top plate (wall portion), 21a . . . upper surface (outer surface), 22 . . . bottom plate (wall portion), 23 . . . side wall (wall portion), 23a . . . outer surface, 24 . . . rear wall (wall portion), 24a . . . rear surface (outer surface), 41 . . . rib (thin portion), 42 . . . flange (thin portion), 43 . . . rib (thin portion), 44 . . . rib (thin portion), 50 . . . mold, 50s . . . cavity, 51 . . . mold body (first mold body), 51a . . . gate, 52 . . . mold body (second mold body), 53 . . . mold insert (first mold insert), 54 . . . mold insert (second mold insert), 60 . . . label, 61 . . . base material, 61b . . . back surface (one surface), 62 . . . adhesive material, 62b . . . groove, B1 . . . boundary, B2 . . . boundary, DL1, DL2, DL5, DL6 . . . parting line (first parting line), DL7 . . . parting line (second parting line), G . . . gas, GM . . . gate mark, MR . . . molten resin.

1. A substrate storage container comprising a container body capable of storing a substrate, the container body comprising:
a wall portion defining a storage space for storing the substrate;
a thin portion integrally formed with the wall portion and being thinner than the wall portion; and
one or more parting lines provided on an outer surface of the wall portion and formed along a boundary between a mold body and a mold insert used for injection molding of the container body,
wherein the one or more parting lines include a first parting line passing through the thin portion.

2. The substrate storage container according to claim 1,
wherein the container body further comprises a gate mark provided on the wall portion, the gate mark being a mark of a gate into which molten resin flows during the injection molding, and
wherein the one or more parting lines include a second parting line provided at a position spaced from the gate mark by a predetermined distance or more.

3. The substrate storage container according to claim 1, further comprising a label attached to the outer surface of the wall portion along any of the one or more parting lines.

4. The substrate storage container according to claim 3,
wherein the label comprises a base material and an adhesive material provided on one surface of the base material, and
wherein a groove is provided in the adhesive material.

5. A method for manufacturing a substrate storage container comprising:
preparing a mold for injection molding of a container body including a wall portion that defines a storage space for storing a substrate, the mold including a first mold body, a second mold body, and a first mold insert fitted into the first mold body; and
forming the container body by injecting molten resin into a cavity within the mold from a gate provided in the mold,
wherein a boundary between the first mold insert and the first mold body is located in a portion of the mold that, in the cavity within the mold, defines a region where a flow rate of the molten resin is higher than in a region for forming the wall portion.

6. The method for manufacturing a substrate storage container according to claim 5,
wherein the mold further includes a second mold insert fitted into the first mold body or the second mold body, and
wherein a boundary between the second mold insert and the first mold body or a boundary between the second mold insert and the second mold body is located in a portion of the mold that defines a region of the cavity within the mold that is last filled with the molten resin injected from the gate.
